(19) United States
(12) Patent Application Publication
(10) Pub. No.: US 2025/0141393 A1
(43) Pub. Date: May 1, 2025

(54) PHOTOVOLTAIC DEVICE AND WIRELESS CHARGING DEVICE INCLUDING THE SAME

(71) Applicant: SK hynix Inc., Icheon-si (KR)

(72) Inventor: Jae Hyung JANG, Icheon-si (KR)

(21) Appl. No.: 18/617,481

(22) Filed: Mar. 26, 2024

(30) Foreign Application Priority Data
Oct. 27, 2023 (KR) 10-2023-0145647

(51) Int. Cl. H02S 10/10; B60L 53/12; B60L 53/51; H02J 7/35; H02J 50/00; H02S 20/23; H10N 30/30; H10N 39/00

(52) U.S. Cl. CPC H02S 10/10; B60L 53/12; B60L 53/51; H02J 7/35; H02J 50/00; H02S 20/23; H10N 39/00; H10N 30/30

(57) ABSTRACT

A photovoltaic device and a wireless charging device including the same are disclosed. In an embodiment, a photovoltaic device includes a piezoelectric module configured to receive a pressure and to generate first electrical energy by converting energy from the received pressure into the first electrical energy, and a photovoltaic module configured to receive the first electrical energy generated from the received pressure by the piezoelectric module and configured to include a single photon avalanche diode (SPAD) configured to be powered by using the first electrical energy from the piezoelectric module to generate a current signal by responding to incident light incident upon the photovoltaic module.

### PRIORITY CLAIM AND CROSS-REFERENCE TO RELATED APPLICATION

This patent document claims the priority and benefits of Korean patent application No. 10-2023-0145647, filed on Oct. 27, 2023, the disclosure of which is incorporated herein by reference in its entirety as part of the disclosure of this patent document.

### TECHNICAL FIELD

The technology and embodiments disclosed in this patent document generally relate to a wireless charging device, and more particularly to a wireless charging device including a photovoltaic device.

### BACKGROUND

Wireless charging technology is based on the principle that, when a current is generated in a transmission (Tx) module installed in a wireless charging device and a magnetic field is emitted to the outside, an induced current is generated by the magnetic field in a reception (Rx) module of electrical/electronic equipment that requires charging.

Recently, for the convenience of charging electrical/electronic equipment, various wireless charging technologies are being intensively researched to replace the wired charging technology, which requires a wire that connects a battery to a charger. Wireless charging technology can be applied to any equipment that requires electrical energy charging.

In the automobile field, technology for charging batteries in automobiles is also required due to the spread of electric vehicles.

### SUMMARY

In an embodiment of the disclosed technology, a photovoltaic device may include: a piezoelectric module configured to receive a pressure and to generate first electrical energy by converting energy from the received pressure into the first electrical energy; and a photovoltaic module configured to receive the first electrical energy generated from the received pressure by the piezoelectric module and configured to include a single photon avalanche diode (SPAD) configured to be powered by using the first electrical energy from the piezoelectric module to generate a current signal by responding to incident light incident upon the photovoltaic module.

In an embodiment of the disclosed technology, a photovoltaic device may include: a piezoelectric module configured to convert pressure applied from a vehicle into electrical energy; and a photovoltaic module including a single photon avalanche diode (SPAD) configured to operate using the electrical energy generated by the piezoelectric module and generate a current by converting light incident upon the photovoltaic module.

In some implementations, the photovoltaic device may further include an energy storage unit configured to receive and to store the first electrical energy generated by the piezoelectric module, and the energy storage unit may be further configured to receive the current signal generated by the SPAD to generate second electrical energy and to store the second electrical energy.

In some implementations, the energy storage unit may generate a magnetic field by supplying an electric current to a wireless charging transmitter.

In some implementations, the energy storage unit may supply power to a light emitting device configured to emit light.

In some implementations, the photovoltaic module may include a pulse counter configured to receive a pulse signal generated by the SPAD in response to the incident light.

In some implementations, the pulse counter may determine a frequency of the pulse signal received from the SPAD.

In some implementations, the photovoltaic device may further include: a light emitting device configured to emit light to the outside by generating the light using the first electrical energy, wherein the light emitting device is configured to emit light when the determined frequency of the pulse signal is less than or equal to a predetermined threshold.

In some implementations, the piezoelectric module includes at least one of a lead zirconate titanate (PZT)-based material or a BaTiO₃.

In another embodiment of the disclosed technology, a wireless charging device including a photovoltaic device may include: a piezoelectric module disposed below a road surface on which a vehicle travels and configured to convert pressure applied from the vehicle into electrical energy; a photovoltaic module provided with a single photon avalanche diode (SPAD), that is driven by electrical energy converted by the piezoelectric module and generates a current in response to light received from the outside; and an energy storage unit configured to store electrical energy converted by the piezoelectric module and electrical energy caused by a current generated by the photovoltaic module.

In another embodiment of the disclosed technology, a wireless charging device including a photovoltaic device may include: a piezoelectric module disposed below a road surface on which a vehicle travels, and configured to generate first electrical energy by converting pressure applied from the vehicle into the first electrical energy; a photovoltaic module including a single photon avalanche diode (SPAD) configured to operate using the first electrical energy generated by the piezoelectric module, the photovoltaic module configured to generate an electric current in response to light incident upon photovoltaic module from the outside; and an energy storage unit configured to store: the first electrical energy generated by the piezoelectric module; and second electrical energy generated from the electric current generated by the photovoltaic module.

In some implementations, the wireless charging device may further include a wireless charging transmitter configured to receive an electric current from the energy storage unit and to emit a magnetic field to the outside.

In some implementations, the photovoltaic module may be disposed in a roof region located above the road surface, wherein the roof region is spaced apart from the road surface by a predetermined distance.

In some implementations, the photovoltaic module is connected to the energy storage unit by electrical wires included in a certain structure through which a roof region and the road surface are connected to each other.

In some implementations, the wireless charging device may further include a light emitting device configured to receive power from the energy storage unit and to emit light to the outside.

In some implementations, the light emitting device is disposed in a roof region located above the road surface, wherein the roof region is spaced apart from the road surface by a predetermined distance.

In some implementations, the light emitting device may include a photovoltaic device disposed below the road surface.

In another embodiment of the disclosed technology, a method for operating a photovoltaic device may include: converting pressure applied from a vehicle into electrical energy; driving a photovoltaic module using the electrical energy; and generating a current in response to light incident upon the photovoltaic module.

In another embodiment of the disclosed technology, a method for operating a photovoltaic device may include: converting a pressure into first electrical energy; operating a photovoltaic module using the first electrical energy; and generating second electrical energy generated from an electric current generated in response to incident light incident upon the photovoltaic module.

In some implementations, the method for operating the photovoltaic device may further include: determining, by a photovoltaic module, a frequency of a pulse signal generated in response to the incident light.

The method for operating the photovoltaic device may further include emitting light to the outside upon determination that the determined frequency of the pulse signal is less than or equal to a predetermined threshold.

The method for operating the photovoltaic device may further include supplying the electric current to a wireless charging transmitter configured to generate a magnetic field to the outside.

The method for operating the photovoltaic device may further include storing the first electrical energy and the second electrical energy generated from the electric current.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of a photovoltaic device based on some implementations of the disclosed technology.

FIG. 2 is a flowchart illustrating an example method for operating the photovoltaic device shown in FIG. 1 based on some implementations of the disclosed technology.

FIG. 3 is a flowchart illustrating an example of how to determine the criteria for turning on and off a light emitting device shown in FIG. 1 based on some implementations of the disclosed technology.

FIG. 4 is a schematic diagram illustrating an example of the photovoltaic device shown in FIG. 1 based on some implementations of the disclosed technology.

FIG. 5A is a cross-sectional view illustrating an example of a wireless charging device including the photovoltaic device shown in FIG. 1 based on some implementations of the disclosed technology. FIG. 5B is a plan view illustrating an example of a wireless charging device including the photovoltaic device shown in FIG. 1 based on some implementations of the disclosed technology.

FIG. 6A is a cross-sectional view illustrating another example of the wireless charging device including the photovoltaic device shown in FIG. 1 based on some implementations of the disclosed technology. FIG. 6B is a three-dimensional (3D) view illustrating another example of the wireless charging device including the photovoltaic device shown in FIG. 1 based on some implementations of the disclosed technology.

FIG. 7 is a cross-sectional view illustrating an example of a partial structure of a photovoltaic module shown in FIG. 1.

FIG. 8 is a cross-sectional view illustrating an example structure of a single photon avalanche diode (SPAD) shown in FIG. 7 based on some implementations of the disclosed technology.

### DETAILED DESCRIPTION

This patent document provides embodiments and examples of wireless charging devices including photovoltaic devices that may be used to substantially address one or more technical or engineering issues in some other wireless charging devices. Some embodiments of the disclosed technology relate to a wireless charging device that includes a photovoltaic device and a wireless charging road that can charge a vehicle battery while the vehicle is running on the road. The wireless charging device based on some implementations of the disclosed technology can convert pressure that is applied to the road surface by the vehicle running on the road into electrical energy, which can be used to operate the photovoltaic device, thereby wirelessly charging the vehicle running on the road without requiring the wireless charging device to receive electrical energy from a separate power source.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

In describing the components of the embodiments of the disclosed technology, various terms such as first, second, etc., may be used solely for the purpose of differentiating one component from another, but the essence, order and sequence of the components are not limited to these terms. Unless defined otherwise, all terms, including technical and scientific terms, used in the disclosed technology may have the same meaning as commonly understood by a person having ordinary skill in the art to which the disclosed technology pertains. It will be further understood that terms, such as those defined in commonly used dictionaries, may be interpreted as having a meaning that is consistent with their meaning in the context of the related art and the disclosed technology, and should not be interpreted in an idealized or overly formal sense unless expressly so defined herein.

It is to be understood that both the foregoing general description and the following detailed description of the disclosed technology are illustrative and explanatory and are intended to provide further explanation of the disclosure as claimed.

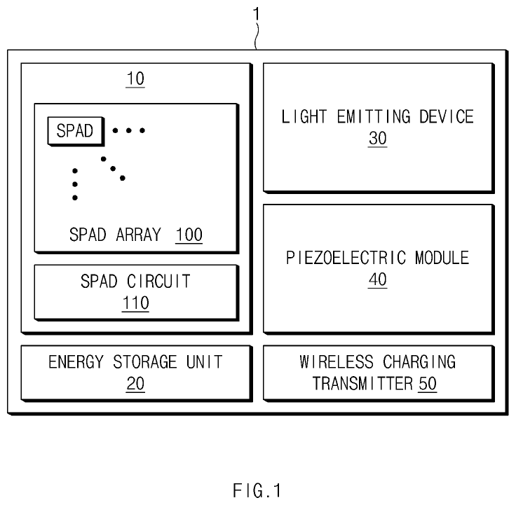

Hereinafter, the following embodiments of the disclosed technology will be described in detail with reference to FIGS. 1 to 8.

FIG. 1 is a block diagram illustrating an example of a photovoltaic device 1 based on some implementations of the disclosed technology.

Referring to FIG. 1, the photovoltaic device 1 may refer to a device that generates electrical energy in response to incident light from the outside. For example, the photovoltaic device 1 may include a solar cell, a photodiode, and/or a single photon avalanche diode (SPAD). In some implementations, the photovoltaic device uses the photoelectric effect to generate electrical energy in response to the incident light, but the disclosed technology is not limited thereto. In some implementations, the photovoltaic device 1 may include a device equipped with an element for generating electrical energy in response to incident light. In some implementations, the photovoltaic device 1 may be a device that includes a single photon avalanche diode (SPAD) and generates electrical energy in response to incident light.

The photovoltaic device 1 may include a photovoltaic module 10, an energy storage unit 20, a light emitting device 30, a piezoelectric module 40, and a wireless charging transmitter 50.

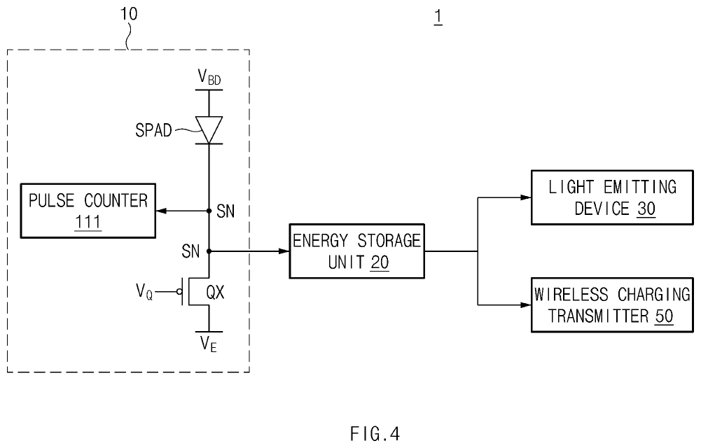

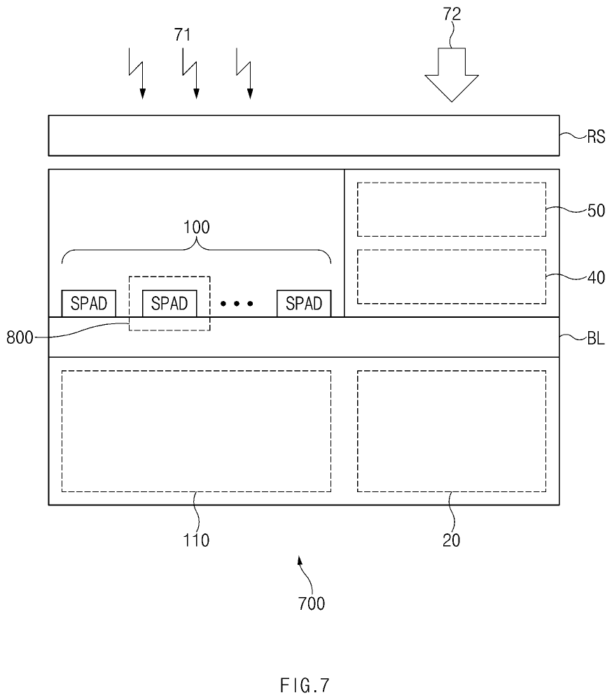

The photovoltaic module 10 may be an example of a photovoltaic device that generates electrical energy in response to incident light. The photovoltaic module 10 may include a single photon avalanche diode (SPAD) to convert optical energy of the incident light into electrical energy. The photovoltaic module 10 may include an SPAD array 100 and an SPAD circuit 110. Examples of the operation and structure of the photovoltaic module 10 will be described later with reference to FIGS. 4 and 7.

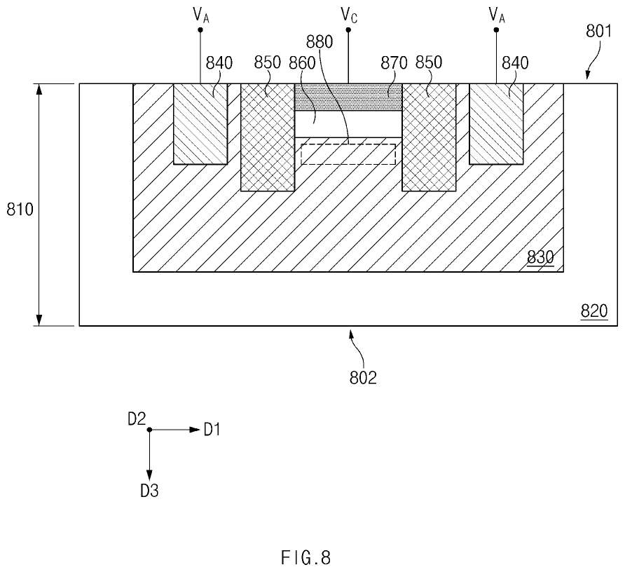

A single photon avalanche diode (SPAD) array 100 may include one or more SPADs. The SPAD in the photovoltaic device 1 may include a light receiving unit upon which light is incident. A reverse bias voltage may be applied to the SPAD. The intensity of the reverse bias voltage applied to the SPAD may be greater than the intensity of a breakdown voltage. When the SPAD receives the incident light from the outside upon receiving a reverse bias voltage higher than the breakdown voltage, the SPAD may generate a current. Examples of the SPAD will be discussed below with reference to FIGS. 4 and 8.

The SPAD circuit 110 may transmit the current generated from the SPAD to the energy storage unit 20. The SPAD circuit 110 may include a pulse counter capable of detecting a pulse signal generated from the SPAD. The pulse counter will be described later with reference to FIG. 4. The SPAD circuit 110 may perform operations using electrical energy stored in the energy storage unit 20 or electrical energy converted by the piezoelectric module 40.

The energy storage unit 20 may receive the current generated by the photovoltaic module 10 and store the received current in the form of electrical energy. For example, the energy storage unit 20 may be implemented with one or more capacitors that can operate as a battery for storing electrical energy. The energy storage unit 20 may receive electrical energy generated by the piezoelectric module 40 and store the received electrical energy. The energy storage unit 20 may supply electrical energy to the light emitting device 30 or the wireless charging transmitter 50.

The light emitting device 30 may generate light using the electrical energy and emit the light to the outside of the photovoltaic device 1. For example, the light emitting device 30 may be one of a laser diode, a light emitting diode (LED), a near infrared laser (NIR), a point light source, or a combination thereof. The electrical energy used by the light emitting device 30 may be, for example, electrical energy supplied from the energy storage unit 20. In some implementations, the light emitting device 30 may emit light to the outside of the photovoltaic device 1 when the amount of external light is insufficient due to sunset, solar eclipse or bad weather. Light emitted to the outside from the light emitting device 30 may be reflected by an object existing outside, and the reflected light may be incident upon the photovoltaic module 10. For example, in a situation where the photovoltaic device 1 is disposed below a road surface and is designed to allow external light to pass therethrough, if the light emitting device 30 emits light in an upward direction from the road, the emitted light may be reflected by vehicles running on the road and enter the photovoltaic module 10 disposed below the road surface.

The piezoelectric module 40 may include a piezoelectric material that can generate electrical energy by pressure applied from the outside. The piezoelectric material may include, for example, at least one of PTZ-based material (e.g., a material containing lead (Pb), titanium (Ti), and zirconium (Zr)) and BaTiO₃, but the disclosed technology is not limited thereto. For example, the piezoelectric module 40 may be disposed below the road surface on which a vehicle travels, and the piezoelectric module 40 may generate electrical energy by detecting pressure applied to a region of the road surface through which the vehicle passes.

The wireless charging transmitter 50 may generate a magnetic field that induces current in a wireless charging receiver that can be disposed inside the vehicle, and may emit the magnetic field to the outside. The wireless charging transmitter 50 may receive electrical energy from the energy storage unit 20, and the wireless charging transmitter 50 may contain a wire therein so that a current can flow through the wire. When a current flows in the wireless charging transmitter 50, a magnetic field may be formed outside the photovoltaic device 1, enabling wireless charging. As an example, the wireless charging transmitter 50 may be disposed below a road surface on which a vehicle can travel, but the disclosed technology is no limited thereto, and for example, the wireless charging transmitter 50 may be disposed at a parking area in a parking lot. As another example, the wireless charging transmitter 50 may emit a magnetic field in an upward direction from the road. When a magnetic field is formed, an induced current may occur in the vehicle so that the vehicle can be charged with electricity. The wireless charging transmitter 50 may be provided in the photovoltaic device 1 when the photovoltaic device 1 is used to implement a wireless charging function.

In some embodiments, the photovoltaic device 1 may be implemented without the light emitting device 30 or the wireless charging transmitter 50. For example, the driving vehicle applies pressure to the piezoelectric module 40, which converts the pressure to electrical energy, and the photovoltaic device 1 may operate the photovoltaic module 10 using the electrical energy converted by the piezoelectric module 40, and the photovoltaic module 10 may generate electrical energy in response to incident light and store the generated electrical energy.

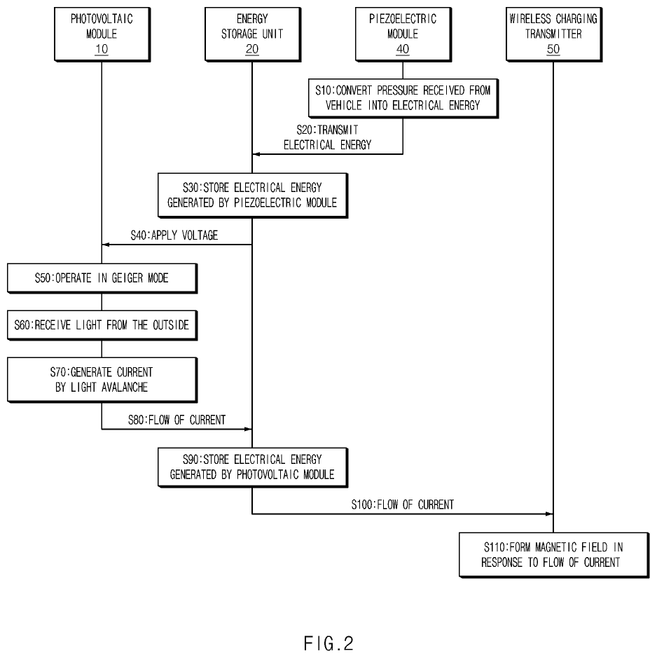

FIG. 2 is a flowchart illustrating an example method for operating the photovoltaic device 1 shown in FIG. 1 based on some implementations of the disclosed technology.

The flowchart of FIG. 2 shows an example flowchart for an embodiment in which the photovoltaic device 1 is disposed below the road surface to implement a wireless charging function.

Referring to FIGS. 1 and 2, the piezoelectric module 40 may convert the pressure applied from the vehicle into electrical energy (S10). The piezoelectric module 40 may be disposed below the road surface, so that the piezoelectric module 40 can detect pressure applied to the road surface or vibration energy caused by the vehicle.

The electrical energy converted by the piezoelectric module 40 may be transmitted to the energy storage unit 20 (S20).

The energy storage unit 20 may store the received electrical energy (S30). The energy storage unit 20 may supply the stored electrical energy to other components required to receive electrical energy. As an example, the energy storage unit 20 may apply voltage to the photovoltaic module 10 (S40). For example, the magnitude of the voltage supplied to the photovoltaic module 10 may be greater than the breakdown voltage of the SPAD included in the photovoltaic module 10.

The photovoltaic module 10 may operate in a Geiger mode upon receiving a reverse bias voltage having a greater magnitude than the breakdown voltage (S50). The Geiger mode may refer to an operation mode in which a predetermined pulse signal indicating a voltage change can be generated by avalanche breakdown caused by a single photon received from the outside. The reverse bias voltage may be an operating voltage that allows the photovoltaic module 10 to operate in the Geiger mode.

After the photovoltaic module 10 receives the reverse bias voltage higher than the breakdown voltage as the operating voltage, upon receiving light from the outside (S60), avalanche breakdown may be induced so that a voltage pulse may be generated and cause a current to flow in the photovoltaic module 10 (S70). The photovoltaic module 10 may produce a high-level output by inducing emission of multiple photons using only a single photon.

The current generated by the photovoltaic module 10 may flow to the energy storage unit 20 (S80). The energy storage unit 20 may store electrical energy generated by the photovoltaic module 10 (S90). Electrical energy stored in the energy storage unit 20 may be supplied to the wireless charging transmitter 50 (S100).

The wireless charging transmitter 50 may generate a magnetic field and emit it to the outside of the photovoltaic device 1 using the received electrical energy. The emitted magnetic field may enable a charging function by generating an induced current in the wireless charging receiver capable of being installed in a vehicle driving on the road.

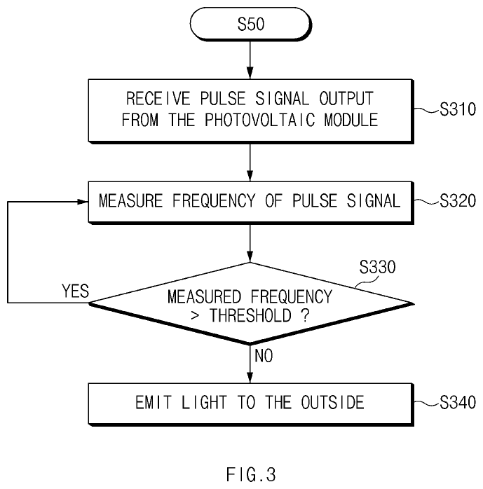

FIG. 3 is a flowchart illustrating an example of a method of how to determine the criteria for turning on and off the light emitting device 30 shown in FIG. 1 based on some implementations of the disclosed technology.

The amount of light that can be received from the outside may be affected by time of day or weather. FIG. 3 is a flowchart showing an example of a reference by which the light emitting device 30 can determine whether to emit light to the outside, and may correspond to one or more of the embodiments discussed in this patent document. In relation to FIG. 2, the flowchart of FIG. 3 may show an example operation related to the light emitting device 30 that can be operated between two operations S50 and S60 of FIG. 2.

Referring to FIGS. 1 and 3, a pulse counter included in the SPAD circuit 110 may detect the pulse signal output from the SPAD (S310). The number of detected pulses in the pulse signal may be a parameter indicating how much current the SPAD generates in response to incident light. As light is more frequently incident upon the SPAD, the number of detected pulses in the pulse signal increases, so that the SPAD generates the current based on the increased number of pulses in the pulse signal.

A pulse counter may measure the frequency of the pulse signal (e.g., count the number of pulses in the pulse signal). When the amount of light incident from the outside is sufficient, the frequency of the pulse signal may be sufficiently high, and when the amount of light is insufficient, the frequency of the pulse signal may be low. In some embodiments, a dark counter rate (DCR) can be used as a threshold for determining whether the amount of incident light is large or small.

The DCR may refer to a parameter indicating the frequency of the pulse signal detected in absence of light. In one example, the DCR may be measured in a dark space completely blocked from any light source. In order to calculate the DCR, the pulse signal output from the SPAD may be recorded, and the number of recorded pulses in the pulse signal may be divided by the time corresponding to a measurement period. In general, DCR may be indicated by the number of pulses generated per second, and may be indicated by the number of pulses generated per unit time within a unit area. For example, a DCR index of each SPAD may have a value between 100 cps/μm² and 1000 cps/μm².

The threshold may be set to a value greater than the measured DCR index, so that it may be possible to consider the fact that, even in the environment where there is insufficient external light (e.g., at night), external light such as car lights, surrounding streetlights, or moonlight may exist. As another example, the threshold is a value for distinguishing between various environments such as daytime, nighttime, or bad weather. For example, the threshold may be set to the frequency of pulse signals generated by the SPAD at a specific time after sunset or before sunrise.

The pulse counter may compare the calculated frequency of pulse signals with a predetermined threshold (S330). In some implementations, it can be determined whether the frequency of the pulse signal (e.g., the number of pulses in the pulse signal) is greater than the predetermined threshold.

If the calculated frequency of pulse signals is greater than the predetermined threshold (YES in S330), this means that the amount of light incident from the outside is sufficient. When the amount of light incident from the outside is sufficient (e.g., during the daytime without bad weather), the light emitting device 30 may be turned off because a separate light source is unnecessary, and the pulse counter may continuously monitor and calculate the frequency of pulse signals.

If the calculated frequency of pulse signals is less than a predetermined threshold (NO in S330), this means that the amount of light incident from the outside is insufficient. When the amount of light incident from the outside is insufficient (e.g., bad weather, at night, etc.), a separate light source is required, so that the light emitting device 30 may be turned on.

The light emitting device 30 in the “on” state may emit light to the outside. Light emitted to the outside of the photovoltaic device 1 by the light-emitting device 30 may be reflected by a running vehicle, and the reflected light may enter the photovoltaic module 10 of the photovoltaic device 1.

FIG. 4 is a schematic diagram illustrating an example of the photovoltaic device 1 shown in FIG. 1 based on some implementations of the disclosed technology.

The photovoltaic device 1 shown in FIG. 1 may generate electrical energy in response to incident light and may supply a current for providing the wireless charging function, and an example of the photovoltaic device 1 shown in FIG. 1 is briefly illustrated in FIG. 4.

Referring to FIGS. 1 and 4, the photovoltaic device 1 may include a photovoltaic module 10, an energy storage device 20, a light emitting device 30, and a wireless charging transmitter 50.

The SPAD circuit 110 may include an SPAD, a quenching transistor (QX), and a pulse counter 111. The SPAD may detect a single photon of incident light, and may generate a voltage-based pulse signal corresponding to the detected single photon. The SPAD may be a photoelectric converter (e.g., photodiode) including a photosensitive P-N junction. In one example, the SPAD may be a diode of which avalanche breakdown is caused by a single photon incident in the Geiger mode, in which a cathode-anode voltage corresponding to a reverse bias voltage is higher than a breakdown voltage, is applied to the SPAD. One terminal of the SPAD may receive a first bias voltage (V_{BD}) required for transition to the Geiger mode. For example, the first bias voltage (V_{BD}) may be a voltage such that the value obtained by subtracting a second bias voltage (V_{E}) from the first bias voltage (V_{BD}) becomes a negative voltage with an absolute value higher than an absolute value of the breakdown voltage. The other terminal of the SPAD may be connected to a sensing node (SN), and the SPAD may output a voltage pulse generated by sensing a single photon to the sensing node (SN).

A quenching transistor (QX) may perform a quenching operation to reset the voltage of the sensing node (SN) to the second bias voltage (V_{E}), when a voltage of the sensing node (SN) decreases due to a voltage pulse signal resulting from avalanche breakdown. One terminal of the quenching transistor (QX) may receive the second bias voltage (V_{E}) for applying, to the SPAD, a reverse bias voltage that enables the SPAD to operate in the Geiger mode. For example, the second bias voltage (V_{E}) may be a voltage such that the value obtained by subtracting the second bias voltage (V_{E}) from the first bias voltage (V_{BD}) becomes a negative voltage with an absolute value higher than an absolute value of the breakdown voltage. The other terminal of the quenching transistor (QX) may be connected in the direction of the sensing node (SN), and when the quenching transistor (QX) is turned on by a quenching voltage (VQ), the voltage of the sensing node (SN) may return to the second bias voltage (V_{E}).

In some implementations, the quenching transistor (QX) may be a P-type metal-oxide semiconductor field effect transistor (PMOSFET), a gate terminal of which receives a quenching voltage (VQ). The quenching voltage (Vo) may have a turn-on voltage when the voltage of the sensing node (SN) decreases due to generation of a voltage pulse signal, and may have a turn-off voltage when the voltage of the sensing node (SN) returns to the second bias voltage (V_{E}).

The two sensing nodes (SNs) shown in FIG. 4 may be the same node. When avalanche breakdown occurs, a current may be generated in the SPAD, and the generated current may move to the energy storage unit 20 through the sensing node (SN). The electrical energy stored in the energy storage unit 20 may be supplied to the light emitting device 30 in the environment where the amount of light is insufficient so that light can be emitted to the outside of the photovoltaic device 1. The energy storage unit 20 may provide electrical energy to the wireless charging transmitter 50 so that a magnetic field for providing the wireless charging function can be emitted to the outside of the photovoltaic device 1.

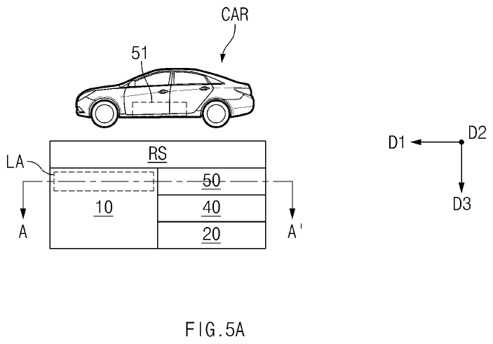

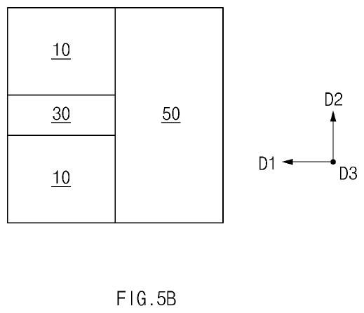

FIG. 5A is a cross-sectional view illustrating an example of a wireless charging device including the photovoltaic device 1 shown in FIG. 1 based on some implementations of the disclosed technology. FIG. 5B is a plan view illustrating an example of a wireless charging device including the photovoltaic device 1 shown in FIG. 1 based on some implementations of the disclosed technology.

FIG. 5A illustrates a cross-sectional view of an example where the photovoltaic module 10 of the photovoltaic device 1 is disposed below the road surface (RS), and FIG. 5B illustrates a plan view of an example where the photovoltaic module 10 of the photovoltaic device 1 is disposed below the road surface (RS). The width of a second direction (D2) shown in FIG. 5B may correspond to the width of one lane of the road. In addition, FIG. 5B is a cross-sectional view illustrating the wireless charging device taken along the line A-A′ of FIG. 5A.

Referring to FIG. 5A, the wireless charging transmitter 50 may be disposed in some of the lower portions of the road surface (RS). The wireless charging transmitter 50 may generate an induced current generated in the wireless charging receiver 51 of the vehicle (CAR) to form a magnetic field with a strength sufficient to charge a battery (e.g., secondary battery in an electric vehicle) on the road surface (RS). In some implementations, the wireless charging transmitter may be arranged closer to the road surface (RS) than the energy storage unit 20 or the piezoelectric module 40.

The photovoltaic module 10 may be disposed below the road surface (RS) where the wireless charging transmitter 50 is not disposed. The wireless charging transmitter 50 and the photovoltaic module 10 may be arranged to be in contact with each other in a first direction (D1). The first direction (D1) may be a direction in which the vehicle (CAR) travels on the road. The photovoltaic module 10 may include a light transmission region (LA) through which external light may be incident in a third direction (D3) from the upper portion of the road surface (RS), and the light transmission region (LA) may be disposed closer to the road surface (RS) than the energy storage unit 20 or the piezoelectric module 40.

The piezoelectric module 40 may be disposed at a depth where vibration energy or pressure applied to the road surface (RS) by the vehicle (CAR) can be detected. As an example, the piezoelectric module 40 may be disposed below the wireless charging transmitter 50.

The energy storage unit 20 may be located farther from the road surface (RS) than the wireless charging transmitter 50, the piezoelectric module 40, or the photovoltaic module 10. As an example, the energy storage unit 20 may be located deeper than the wireless charging transmitter 50 and the piezoelectric module 40.

Referring to FIG. 5B, when viewed in the third direction (D3) perpendicular to the road surface (RS), the wireless charging transmitter 50 and the photovoltaic module 10 may be arranged adjacent to each other. The photovoltaic module 10 may be arranged to overlap a region in which wheels of the vehicle (CAR) traveling along the lane of the road may come into contact with the road surface (RS) in the third direction (D3).

The light emitting device 30 may be disposed between the photovoltaic modules 10 disposed on both sides of the photovoltaic device. The light emitting device 30 may be disposed along the center of the lane to increase the frequency at which light emitted from the light emitting device 30 to the outside collides with and is reflected from a bottom surface of the vehicle (CAR) traveling along the lane.

The photovoltaic devices 1 shown in FIGS. 5A and 5B may be repeatedly arranged in the proceeding direction of the road at a lower portion of an extended line of the road surface (RS). In addition, the photovoltaic module 10 may be additionally disposed on a shoulder of the road so that the area of the light transmission region (LA) may increase.

The road surface (RS) may include a material (e.g., transparent tempered glass, etc.) that can sufficiently withstand load or weight applied to the road surface (RS) and has high light transmittance.

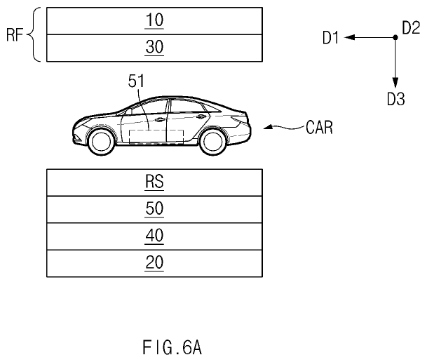

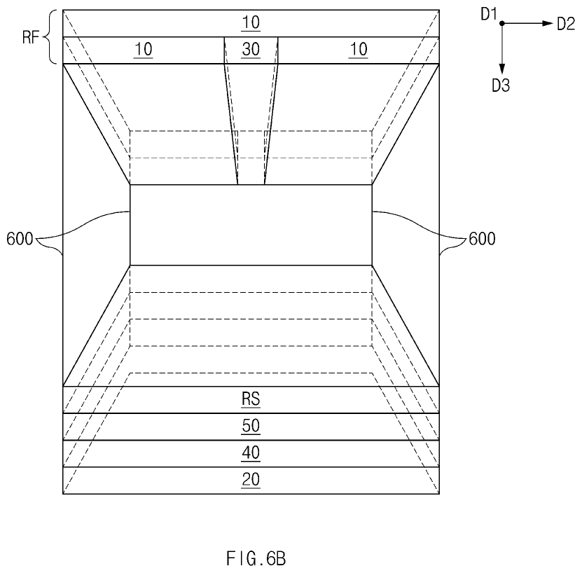

FIG. 6A is a cross-sectional view illustrating another example of the wireless charging device including the photovoltaic device 1 shown in FIG. 1 based on some implementations of the disclosed technology. FIG. 6B is a three-dimensional (3D) view illustrating another example of the wireless charging device including the photovoltaic device 1 shown in FIG. 1 based on some implementations of the disclosed technology.

FIG. 6A illustrates a cross-sectional view of an example where the photovoltaic module 10 of the photovoltaic device 1 is disposed above the road surface (RS), and FIG. 6B illustrates a plan view of an example where the photovoltaic module 10 of the photovoltaic device 1 is disposed above the road surface (RS).

Referring to FIG. 6A, a roof structure (RF) spaced apart from the road surface (RS) by a predetermined distance may include a photovoltaic module 10 and a light emitting device 30. The predetermined distance may be a height (e.g., 5m or more) high enough to allow a large truck or an express bus to pass safely.

The photovoltaic module 10 may be disposed at an upper portion of the roof structure (RF). The photovoltaic module 10 may receive light incident upon the upper portion of the roof structure (RF).

The light emitting device 30 may be disposed at a lower portion of the roof structure (RF). The light emitting device 30 may emit light in the third direction (D3), and the emitted light may be reflected by the road surface (RS) or the driving vehicle (CAR) so that the reflected light can be incident upon the bottom surface of the roof structure (RF).

A wireless charging transmitter 50 may be disposed below the road surface (RS). A piezoelectric module 40 may be disposed below the wireless charging unit 50. The energy storage unit 20 may be disposed below the piezoelectric module 40.

Referring to FIG. 6B, additional photovoltaic modules 10 may be disposed at a lower portion of the roof structure (RF). The photovoltaic module 10 disposed at the lower portion of the roof structure (RF) may receive light that is emitted by the light emitting device 30, is reflected from the road surface (RS) or the vehicle (CAR), and is finally incident upon the bottom surface of the roof structure (RF).

The roof structure (RF) and the energy storage unit 20 disposed below the road surface (RS) may include a vertical structure 600. The vertical structure 600 may include a predetermined electrical wire through which the photovoltaic module 10, the light emitting device 30, and the energy storage unit 20 are electrically connected to each other.

FIG. 7 is a cross-sectional view illustrating an example of a partial structure of the photovoltaic module 10 shown in FIG. 1.

FIG. 7 is a cross-sectional view illustrating one embodiment in which the photovoltaic module 10 of the photovoltaic device 1 is disposed below the road surface (RS) as shown in FIG. 5A. In other words, FIG. 7 is a more detailed cross-sectional view of the structure shown in FIG. 5A.

Referring to FIGS. 1 and 7, the photovoltaic device 1 may be disposed below the road surface (RS). The SPAD array 100 may include a structure in which one or more SPADs are disposed in a region where incident light 71 can enter the photovoltaic device 1 after passing through the road surface (RS). The SPAD circuit 110 may be disposed below the SPAD array 100. A coupling layer (BL) may be disposed between the SPAD array 100 and the SPAD circuit 110, and the coupling layer (BL) may allow each SPAD disposed in the SPAD array 10 to be electrically connected to the SPAD circuit 110.

The wireless charging transmitter 50 and/or the piezoelectric module 40, which may be disposed adjacent to the SPAD array 100, may be disposed between the road surface (RS) and the coupling layer (BL). The coupling layer (BL) may electrically connect the piezoelectric module 40 to at least one of the SPAD circuit 110 and the energy storage unit 20.

The coupling layer (BL) may include electrical wires through which the SPAD array 100 is electrically connected to the SPAD circuit 110. The coupling layer (BL) may include electrical wires through which the piezoelectric module 40, the SPAD circuit 110, the piezoelectric module 40, and the energy storage unit 20 are electrically connected to each other. The electrical wires may include, for example, copper (Cu).

Pressure 72 applied to the road surface (RS) when the vehicle is running on the road surface (RS) may be transferred to the piezoelectric module 40. The piezoelectric module 40 may generate electrical energy in response to the pressure 72 applied to the road surface (RS), and may transmit the generated electrical energy to the energy storage unit 20 or the SPAD circuit 110.

The energy storage unit 20 may be disposed below the road surface (RS), but is not limited to this. Alternatively, the energy storage unit 20 may also be disposed in a region spaced apart from the road surface (RS) when viewed in a direction perpendicular to the road.

FIG. 8 is a cross-sectional view illustrating an example structure of the SPAD shown in FIG. 7 based on some implementations of the disclosed technology.

Referring to FIG. 8, the SPAD cross-section 800 is a cross-sectional view illustrating an example of one cross-section of the SPAD shown in FIG. 7.

Referring to FIGS. 1, 7, and 8, the SPAD cross-section 800 may include a photoelectric conversion layer 810 and electrodes included in the photoelectric conversion layer 810. Here, each of the electrodes may receive a bias voltage as an input voltage. The photoelectric conversion layer 810 may include a substrate 820, a deep well region 830, an anode region 840, a guard ring region 850, a shallow well region 860, a cathode region 870, and an avalanche region 880. Each of the anode region 840 and the cathode region 870 may receive a bias voltage as an input voltage.

The substrate 820 may be a semiconductor layer doped with impurities of a first conductivity type. For example, the substrate 820 may be an N-type doped silicon region. The substrate 820 may include a first surface 801 arranged in a direction along which the SPAD circuit 110 can be connected to the first surface 801, and a second surface 820 opposite to the first surface 801 to enable external light to be incident thereupon.

The deep well region 830 may be a region doped with impurities of a second conductivity type. The deep well region 830 may be a doped region in which a doping material is implanted from the first surface 801. For example, the deep well region 830 may be a region doped with P-type impurities. The deep well region 830 may form a PN junction with a shallow well region 860 to be described later. When a reverse bias voltage greater than the breakdown voltage is applied to the SPAD and a single photon is incident from the first surface 801, resulting in avalanche breakdown, an avalanche region 880 in which multiple photons occur may be formed in the vicinity of the region where the PN junction is formed.

The anode region 840 may be a region corresponding to a cathode of the SPAD that receives the reverse bias voltage as an operation voltage. The anode region 840 may be a region doped with impurities of a second conductivity type from the first surface 801. Although the anode region 840 of FIG. 8 is illustrated as two separated regions for convenience of description, other implementations are also possible, and it should be noted that the anode region 840 may also be implemented as only one electrode having the same shape as a hollow cylindrical shape. The anode region 840 may be a region that is doped with impurities of a second conductivity type to receive the bias voltage as an input. For example, the anode region 840 may be a P-type doped region, and the concentration of the anode region 840 doped with impurities of a second conductivity type (e.g., P-type impurities) may be higher than the concentration of the deep well region 830 doped with impurities of the second conductivity type (e.g., P type impurities).

The guard ring region 850 may be a region doped with impurities of a first conductivity type. For example, the guard ring region 850 may be an N-type doped ring-shaped region. The guard ring region 850 may be a structure recessed from the first surface 801, and may be a doped region having a ring shape surrounding the periphery of the cathode region 870, which may be placed at the center of the SPAD. In FIG. 8, one cross-section of the ring-shaped guard ring region 850 is shown as if it were two separate regions, but is not limited thereto, and two separate regions may be 3D-connected to each other, forming a 3D structure. The guard ring region 850 may block noise or interference from the external environment, and may be disposed between the cathode region 870 and the anode region 840, so that the guard ring region 850 may isolate two electrodes from each other.

The cathode region 870 may be a negative electrode to which a reverse bias voltage is applied as an input. The cathode region may refer to a region doped with impurities of a first conductivity type on the first surface 801, and the guard ring region 850 may have a higher doping concentration than impurities of the first conductivity type (e.g., N-type impurities)

The shallow well region 860 may be disposed below the cathode region 870, and may be a region doped with impurities of a first conductivity type. The shallow well region 860 may be, for example, an N-type doped region, and the doping concentration of the shallow well region 860 with N-type impurities may be greater than the doping concentration of the guard ring region 850 and lower than the doping concentration of the cathode region 870.

The light avalanche region 880 may be a region in which multiple photons can be generated when the avalanche phenomenon occurs by operating the SPAD in the Geiger mode due to a PN junction which can be formed at a portion where the shallow well region 860 doped with impurities of the first conductivity type and the deep well region 870 doped with impurities of the second conductivity type are in contact with each other. The plurality of photons generated when the avalanche phenomenon occurs in the light avalanche region 880 may be transferred to the SPAD circuit 110 and the energy storage unit 20, such that the resultant photons can be stored in the energy storage unit 20.

As is apparent from the above description, the wireless charging device may provide wireless charging technology that can convert pressure that is applied to the road surface by the vehicle running on the road into electrical energy, and can drive the photovoltaic device and perform wireless charging for the vehicle using the electrical energy, so that the vehicle running on the road need not receive separate electrical energy from the outside.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. A photovoltaic device comprising:
a piezoelectric module configured to receive a pressure and to generate first electrical energy by converting energy from the received pressure into the first electrical energy; and
a photovoltaic module configured to receive the first electrical energy generated from the received pressure by the piezoelectric module and configured to include a single photon avalanche diode (SPAD) configured to be powered by using the first electrical energy from the piezoelectric module to generate a current signal by responding to incident light incident upon the photovoltaic module.

2. The photovoltaic device according to claim 1, further comprising:
an energy storage unit configured to receive and to store the first electrical energy generated by the piezoelectric module; and
the energy storage unit further configured to receive the current signal generated by the SPAD to generate second electrical energy and to store the second electrical energy.

3. The photovoltaic device according to claim 2, wherein the energy storage unit is configured to:
generate a magnetic field by supplying an electric current to a wireless charging transmitter.

4. The photovoltaic device according to claim 2, wherein the energy storage unit is configured to:
supply power to a light emitting device configured to emit light.

5. The photovoltaic device according to claim 1, wherein the photovoltaic module includes:
a pulse counter configured to receive a pulse signal generated by the SPAD in response to the incident light.

6. The photovoltaic device according to claim 5, wherein the pulse counter is configured to:
determine a frequency of the pulse signal received from the SPAD.

7. The photovoltaic device according to claim 6, further comprising:
a light emitting device configured to emit light to an outside by generating the light using the first electrical energy,
wherein the light emitting device is configured to emit light when the determined frequency of the pulse signal is less than or equal to a predetermined threshold.

8. The photovoltaic device according to claim 1, wherein:
the piezoelectric module includes at least one of a lead zirconate titanate (PZT)-based material or a BaTiO₃.

9. A wireless charging device including a photovoltaic device, comprising:
a piezoelectric module disposed below a road surface on which a vehicle travels, and configured to generate first electrical energy by converting pressure applied from the vehicle into the first electrical energy;
a photovoltaic module including a single photon avalanche diode (SPAD) configured to operate using the first electrical energy generated by the piezoelectric module, the photovoltaic module configured to generate an electric current in response to light incident upon photovoltaic module from an outside; and
an energy storage unit configured to store: the first electrical energy generated by the piezoelectric module; and second electrical energy generated from the electric current generated by the photovoltaic module.

10. The wireless charging device according to claim 9, further comprising:
a wireless charging transmitter configured to receive an electric current from the energy storage unit and to emit a magnetic field to the outside.

11. The wireless charging device according to claim 9, wherein the photovoltaic module is disposed in a roof region located above the road surface,
wherein the roof region is spaced apart from the road surface by a predetermined distance.

12. The wireless charging device according to claim 9, wherein the photovoltaic module is connected to the energy storage unit by electrical wires included in a certain structure through which a roof region and the road surface are connected to each other.

13. The wireless charging device according to claim 9, further comprising:
a light emitting device configured to receive power from the energy storage unit and to emit light to the outside.

14. The wireless charging device according to claim 13, wherein the light emitting device is disposed in a roof region located above the road surface,
wherein the roof region is spaced apart from the road surface by a predetermined distance.

15. The wireless charging device according to claim 13, wherein the light emitting device includes a photovoltaic device disposed below the road surface.

16. A method for operating a photovoltaic device comprising:
converting a pressure into first electrical energy;
operating a photovoltaic module using the first electrical energy; and
generating second electrical energy generated from an electric current generated in response to incident light incident upon the photovoltaic module.

17. The method according to claim 16, further comprising:
determining, by a photovoltaic module, a frequency of a pulse signal generated in response to the incident light.

18. The method according to claim 17, further comprising:
emitting light to an outside upon determination that the determined frequency of the pulse signal is less than or equal to a predetermined threshold.

19. The method according to claim 16, further comprising:
supplying the electric current to a wireless charging transmitter configured to generate a magnetic field to an outside.

20. The method according to claim 16, further comprising:
storing the first electrical energy and the second electrical energy generated from the electric current.
